(19) United States
(12) Patent Application Publication
(10) Pub. No.: US 2006/0102080 A1
(43) Pub. Date: May 18, 2006

(54) Reduced particle generation from wafer contacting surfaces on wafer paddle and handling facilities

(75) Inventors: Gary Chao Chin Liu, Castro Valley, CA (US); Jiong Chen, San Jose, CA (US)

Correspondence Address: Bo-In Lin, 13445 Mandoli Drive, Los Altos Hills, CA, 94022, US

(73) Assignee: Advanced Ion Beam Technology, Inc.

(21) Appl. No.: 11/002,598

(22) Filed: Dec. 2, 2004

Related U.S. Application Data
(60) Provisional application No. 60/627,426, filed on Nov. 12, 2004.

(51) Int. Cl. C23C 16/00

(52) U.S. Cl. 118/728

(57) ABSTRACT

An ion implanter includes a wafer pad for supporting wafer thereon. The wafer pad is covered by a wafer coating having at least two layers with each layer composed of a different coating material. The top layer may be PTFE, PFA, FEP, or TEFLON polymer layer. The bottom layer may be a layer that is composed of a soft material with a low duometer reading or a vulcanized elastormer layer, or a silicon layer serving the function as a cushion layer. In general, the top layer is a protective layer that has a friction coefficient less than 0.6 and having a roughness less than 0.4 micron when operated in the implanter for loading and unloading the wafer from the wafer pad.

This application claims priority to pending U.S. provisional patent application entitled WAFER HANDLING WITH SIGNIFICANTLY REDUCED PARTICLE GENERATION FROM WAFER PADDLE AND PADDLE COATING filed Nov. 12, 2004 by Liu and accorded Ser. No. 60/627,426, the benefit of its filing date being hereby claimed under Title 35 of the United States Code.

### BACKGROUND OF THE INVENTION

1. Field of the Invention

The invention relates generally to method and apparatus for ion implantation of semiconductor wafer or other work pieces as implanting objects. More particularly, this invention relates to an improved wafer pads and wafer handling facilities coated with smooth protective layer for reducing friction for smooth loading and unloading application and to reduce contamination caused by particles generated from the coating layer due to the wafer loading and unloading operations.

2. Descriptions of the Prior Art

Conventional wafer pads implemented in an ion implanter are often coated with a layer that usually has a soft, rough porous with high friction (GL) surface. The rough surface of these coating layers causes several technical difficulties. First, due to the porousness, and high friction of the coating surface, small particles are often released from the coating surface as a result of loading and unloading of the wafers that cause the surface particles to loosen and attach to the backside of wafer from the pad coating. The small particles may cause contamination thus adversely affect the quality of the ion implant operation. Second, such surface does not provide good thermal contact and conductivity for cooling purposes. Third, the operations of wafer loading and unloading must be handled with extra care due to the concern that the wafer may be damaged during a loading or unloading process.

Furthermore, contaminating particles may also be generated from the contacting surfaces of the wafer handling facilities. These wafer handling facilities may include but not limited to facilities such as wafer holders, aligners, exchange stations, intermediate stations, and load locks. Contaminated particles are often generated form processes of handling the wafer in different stages of wafer transportations, particularly during the processes of wafer loading and unloading operations.

For the above reasons, for those of ordinary skill in the art, there is a need to provide new and improved layer structure and materials for the wafer pad coating to resolve the above-mentioned difficulties. There is a need to improve the quality of the coating such that the pad coating will have minimal particle generated from the loading and unloading operations such that the coating particle contamination can be reduced. There is a need for a soft coating material such that good contact between the wafer and pad surface can be achieved to provide effective thermal conductivity for wafer cooling purpose. Furthermore, there is a need to reduce the porousness, and high friction of the coating surface to minimize potential wafer damages as the wafers are loaded and unloaded from the wafer pads.

### SUMMARY OF THE PRESENT INVENTION

It is the object of the present invention to provide a new material and layer structure for coating the wafer pads and wafer handling facilities of an ion implanter such that the above-discussed difficulties can be resolved.

Specifically, it is the object of this invention to provide a new coating material and layer structure that the wafer pad and handling facilities are coated with coating surface become smooth and have improved surface quality with reduced particulate release during wafer loading and unloading operation. In a preferred embodiment, the coating layer may be composed of materials of the “TEFLON”-type, such as, PTFE, PFA, FEP, and ETFE (commonly known as “TEFLON”). The layer structure can be either multiple layers with a cushion layer comprising an elastomer and a surface layer of PTFE, PFA, FEP, or ETFE. Alternately, the coating may be a single layer of PTFE, PFA, FEP, or ETFE.

These and other objects and advantages of the present invention will no doubt become obvious to those of ordinary skill in the art after having read the following detailed descriptions of the preferred embodiment that is illustrated in the various drawing figures.

### BRIEF DESCRIPTION OF THE DRAWINGS

FIG. 1 is a side cross sectional view of a wafer pad with a coating layer for a preferred embodiment of this invention.

FIGS. 2A and 2B are cross sectional view and perspective view of a wafer pad with coating layers for preferred embodiments of this invention.

### DETAILED DESCRIPTION OF THE METHOD

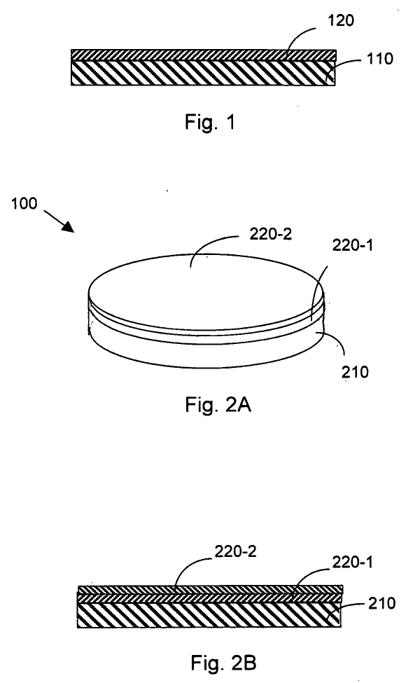

FIG. 1 shows a preferred embodiment of this invention with a wafer pad or a wafer handling facility 100 that includes a wafer-contacting surface 110 coated with a single coating layer 220. The single layer 120 may be a polymer coating having a thickness of 15 to 300 microns coated on the metal substrate 110 of a wafer pad or a wafer handling facility for contacting the wafer backside with reduced friction thus reducing particulate release and minimizing coating material contaminations. The single polymer-coating layer 120 may be a fluoropolymer layer or other polymers including but not limited to PTFE, PFA, or FEP. Thus a wafer pad or a wafer contacting surface of a wafer handling facility for supporting a wafer in an ion implanter now has a coated surface with reduced friction and reduced particle generation. The wafer pad and a wafer contacting surface of a wafer handling facility is coated with a single layer composed of a polymer. In a preferred embodiment, the polymer further includes a fluoropolymer layer.

Referring to FIGS. 2A and 2B for a top view and a side cross sectional view of a wafer pad or a wafer-contacting surface for a wafer-handling facility in an implanter of this invention. The wafer pad or wafer-contacting surface 200 implemented in an ion implanter includes a wafer pad metal substrate 210 that has a high thermal conductivity to enhance the heat dissipation from the pad. The wafer metal substrate 210 is coated with protection layers 220-1 and 220-2. The bottom layer 220-1 is a layer that is composed of a soft material with a low durometer reading having a thickness ranging from 15 to 300 microns. The bottom-coating layer 220-1 may be a silicone layer or an elastomer that is vulcanized onto cooling paddle metal substrate to form a cushion layer. The top coating layer 220-2 is a protective layer that is a thin layer having a thickness ranging from 15 to 300 microns composed of a polymer such as PTFE, PFA, FEP, and fluoropolymer, e.g., ETFE. The top protective layer 220-1 is formed by applying the polymer as a liquid or powder form directly onto the cushion layer 220-1. The protective layer 220-2 has a much lower curing temperature than the material of the cushion layer 220-1 underneath such that the thermal processes when applied to the top protective layer 220-2 will not adversely affect the material properties of the bottom layer 220-1. In addition to the composition as disclosed in the preferred embodiments, the coating materials for the layers 220-1 and 220-2 can further includes additives such as aluminum oxide, boron nitride, graphite, zinc oxide and sliver powder to improve the performance for enhancing the cooling and heat dissipation of the wafer pads. The additives may also be applied to improve other electrical and thermal characteristics of the wafer pads.

In addition to the preferred embodiment as shown in FIGS. 1A and 1B, in an alternate preferred embodiment, For the purpose of reducing particle generation in handling and transporting the wafers during the entire process of loading and unloading wafers from the wafer pads, the same coating and materials are applied to all the wafer contacting surfaces on wafer handling facilities and tools in an ion implanter.

This invention thus discloses an ion implanter that includes a wafer processing facility having a wafer-contacting surface coated with a reduced particle generation surface. In a preferred embodiment, the reduced particle generation surface further comprises a fluoropolymer layer.

This invention further discloses a wafer pad for supporting wafers in an ion implanter wherein the wafer pad includes a coating having at least two layers composed of two different materials.

Additionally, this invention discloses a method of making a wafer pad for an ion implanter. The wafer pad is coated with at least a polymer layer. In a preferred embodiment, the polymer layer has a friction coefficient below 0.6. In a preferred embodiment, the wafer pad further includes a cushion layer below the polymer layer. In a preferred embodiment, the cushion layer has a thermal conductivity in a range of 0.10 to 1.2 Watt/Meter-Kelvin.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

I claim:

1. An ion implanter includes a wafer pad for supporting wafer thereon wherein:
said wafer pad is covered by a wafer costing having at least two layers with each layer composed of a different coating material.

2. The ion implanter of claim 1 wherein:
a top layer of said two layers further comprising a PTFE polymer layer.

3. The ion implanter of claim 1 wherein:
a top layer of said two layers further comprising a PFA polymer layer.

4. The ion implanter of claim 1 wherein:
a top layer of said two layers further comprising a FEP polymer layer.

5. The ion implanter of claim 1 wherein:
a top layer of said two layers further comprising a TEFLON polymer layer.

6. The ion implanter of claim 1 wherein:
a bottom layer of said two layers further comprising a soft material with a low duometer reading.

7. The ion implanter of claim 1 wherein:
a bottom layer of said two layers further comprising a vulcanized elastomer layer.

8. The ion implanter of claim 1 wherein:
a bottom layer of said two layers further comprising a cushion layer.

9. The ion implanter of claim 1 wherein:
a bottom layer of said two layers further comprising a silicon layer.

10. The ion implanter of claim 1 wherein:
a top layer of said two layers further comprising a protective layer having a roughness below 0.4 microns.

11. The ion implanter of claim 1 wherein:
a top layer of said two layers further comprising a protective layer having a friction coefficient below 0.6.

12. The ion implanter of claim 1 wherein:
a bottom layer of said two layers further comprising a cushion layer having a thermal conductivity in a range of 0.10 to 12. W/M.K.

13. The ion implanter of claim 1 wherein:
said wafer coating further composed of a material with an additive comprising aluminum oxide.

14. The ion implanter of claim 1 wherein:
said wafer coating further composed of a material with an additive comprising boron nitride.

15. The ion implanter of claim 1 wherein:
said wafer coating further composed of a material with an additive comprising graphite.

16. The ion implanter of claim 1 wherein:
said wafer coating further composed of a material with an additive comprising zinc oxide.

17. The ion implanter of claim 1 wherein:
said wafer coating further composed of a material with an additive comprising silver.

18. An ion implanter includes a wafer pad for supporting wafer thereon wherein:
said wafer pad is covered by a protective coating layer having a friction coefficient less than 0.6 and a roughness below 0.4 microns.

19. The ion implanter of claim 18 wherein:
said protective coating layer further comprising a PTFE polymer layer.

20. The ion implanter of claim 18 wherein:
said protective coating layer further comprising a PFA polymer layer.

21. The ion implanter of claim 18 wherein:
said protective coating layer further comprising a FEP polymer layer.

22. The ion implanter of claim 18 wherein:
said protective coating layer further comprising a TEFLON polymer layer.

23. An ion implanter includes a wafer pad for supporting wafer thereon wherein:
said wafer pad is covered by a protective polymer coating layer.

24. The ion implanter of claim 23 wherein:
said protective coating layer further comprising a PTFE polymer layer.

25. The ion implanter of claim 23 wherein:
said protective coating layer further comprising a PFA polymer layer.

26. The ion implanter of claim 23 wherein:
said protective coating layer further comprising a FEP polymer layer.

27. The ion implanter of claim 23 wherein:
said protective coating layer further comprising a TEFLON polymer layer.

28. The ion implanter of claim 23 wherein:
said protective coating layer further comprising a polymer coating layer having a friction coefficient less than 0.6.

29. The ion implanter of claim 23 wherein:
a protective coating layer having a roughness below 0.4 microns.

30. The ion implanter of claim 23 wherein:
said protective coating layer further composed of a material with an additive comprising aluminum oxide.

31. The ion implanter of claim 23 wherein:
said protective coating layer further composed of a material with an additive comprising boron nitride.

32. The ion implanter of claim 23 wherein:
said protective coating layer further composed of a material with an additive comprising graphite.

33. The ion implanter of claim 23 wherein:
said protective coating layer further composed of a material with an additive comprising zinc oxide.

34. The ion implanter of claim 23 wherein:
said protective coating layer further composed of a material with an additive comprising silver.

35. An ion implanter includes a wafer handling facility having a wafer-contacting surface wherein:
said wafer-contacting surface is covered by a protective coating layer having a friction coefficient less than 0.6 and a roughness below 0.4 microns.

36. The ion implanter of claim 35 wherein:
said protective coating layer further comprising a PTFE polymer layer.

37. The ion implanter of claim 35 wherein:
said protective coating layer further comprising a PFA polymer layer.

38. The ion implanter of claim 35 wherein:
said protective coating layer further comprising a FEP polymer layer.

39. The ion implanter of claim 35 wherein:
said protective coating layer further comprising a TEFLON polymer layer.

40. An ion implanter includes a wafer handling facility having a wafer-contacting surface for supporting wafer thereon wherein:
said wafer-contacting surface is covered by a protective polymer coating layer.

41. The ion implanter of claim 40 wherein:
said protective coating layer further comprising a PTFE polymer layer.

42. The ion implanter of claim 40 wherein:
said protective coating layer further comprising a PFA polymer layer.

43. The ion implanter of claim 40 wherein:
said protective coating layer further comprising a FEP polymer layer.

44. The ion implanter of claim 40 wherein:
said protective coating layer further comprising a TEFLON polymer layer.

45. The ion implanter of claim 40 wherein:
said protective coating layer further comprising a polymer coating layer having a friction coefficient less than 0.6.

46. The ion implanter of claim 40 wherein:
a protective coating layer having a roughness below 0.4 microns.

47. The ion implanter of claim 40 wherein:
said protective coating layer further composed of a material with an additive comprising aluminum oxide.

48. The ion implanter of claim 40 wherein:
said protective coating layer further composed of a material with an additive comprising boron nitride.

49. The ion implanter of claim 40 wherein:
said protective coating layer further composed of a material with an additive comprising graphite.

50. The ion implanter of claim 40 wherein:
said protective coating layer further composed of a material with an additive comprising zinc oxide.

51. The ion implanter of claim 40 wherein:
said protective coating layer further composed of a material with an additive comprising silver.
